(19) United States
(12) Patent Application Publication
(10) Pub. No.: US 2020/0239266 A1
(43) Pub. Date: Jul. 30, 2020

(54) APPARATUS AND METHOD FOR PROVIDING TETHERED ELECTRICAL POWER TO AUTONOMOUS UNMANNED GROUND VEHICLES

(71) Applicant: Brett Aldrich, Thousand Oaks, CA (US)

(72) Inventor: Brett Aldrich, Thousand Oaks, CA (US)

(21) Appl. No.: 16/748,402

(22) Filed: Jan. 21, 2020

Related U.S. Application Data
(60) Provisional application No. 62/798,253, filed on Jan. 29, 2019.
(60) Provisional application No. 62/798,260, filed on Jan. 29, 2019.

(51) Int. Cl. B65H 75/42; B65H 75/44; G01R 33/07; G05D 1/00; H02G 11/02

(52) U.S. Cl. CPC B65H 75/425; B65H 75/4402; H02G 11/02; B65H 75/4486; G05D 1/0088; G01R 33/072

(57) ABSTRACT

A vehicle includes: an electrical slip ring; a motor-driven cable reel for dispensing and retracting an electrical power cord, wherein the electrical power cord has an electrical plug for connection to an electrical socket, and is electrically connected to the electrical slip ring; a sensor for producing sensor data in response to changes in a rotational position of the motor-driven cable reel; a processor for receiving the sensor data as feedback for commands sent by the processor to the motor-driven cable reel to control a length of the electrical power cord which is dispensed by the motor-driven cable reel; a guide roller, disposed axially parallel to the cable reel, for exerting a force that presses an outermost layer of the electrical power cord against an adjacent layer of the electrical power cord wound around the cable reel, or the cable reel itself; and a level wind assembly for providing transverse movement along an axis parallel to an axis of the cable reel, for controlling the winding, and unwinding, of the electrical power cord around the cable reel.

### CROSS-REFERENCES TO RELATED APPLICATIONS

The present application claims the priority benefit under 35 U.S.C. § 119(e) from U.S. Provisional Patent Application 62/798,252 and U.S. Provisional Patent Application 62/798,260, each of which was filed on 29 Jan. 2019 in the name of Brett Aldrich, and each of which is incorporated herein by reference in its entirety as if fully set forth herein.

### BACKGROUND AND SUMMARY

This invention pertains to the field of automatic/automated/autonomous unmanned ground vehicles (A-UGV), and in particular to A-UGVs which are configured to receive electrical power from an electrical receptacle or outlet via an electrical cord.

The use of A-UGVs to perform a variety of domestic and industrial tasks continues to grow. A-UGVs have wheels, rollers, continuous tracks, mechanical legs (e.g., a biped, quadruped, hexapod, etc.) or other locomotion means which allow them to navigate, for example within a workspace such as an apartment, a factory, a warehouse, etc. In general, an A-UGV may navigate autonomously (“autonomous A-UGV”), or under remote control, for example under human control via a joystick, mouse, trackball, keyboard, etc. A-UGVs have operational advantages due to the lack of need for human intervention, for example lower operating costs (e.g., labor costs), the ability to operate at places and times where remote control is not available, etc.

In many cases, A-UGVs are battery powered, which limits the amount of work they are able to perform due to limitations in the power storage and output capacities of the batteries. Additionally, battery power does not provide sufficient electrical power for A-UGVs to perform certain tasks, or to utilize machine and device components that would be powerful enough to perform such tasks. In addition, as larger and more sophisticated batteries are used to increase the power which can be stored and output to A-UGVs, the size, weight, and expense of the A-UGVs become too large for them to be practically deployed in many environments, such as residential homes or narrow commercial hallways.

So in many situations, it would be desirable to deploy an A-UGV which could operate on power which is provided from an electrical outlet or receptacle (e.g., AC Mains power), for example via an electrical power cord. Such an A-UGV may also include a battery, which may be charged from the electrical power received via the electrical outlet or receptacle. In some cases, the A-UGV may have some reduced or limited operation on batter power, for example, the robot may be able to navigate over some distance on battery power alone.

Accordingly, it would be advantageous to provide an A-UGV which can autonomously locate, connect to, and disconnect from common 110V, 220V (and their international equivalent) household, commercial, and industrial electrical outlets and receptacles (i.e., connected to AC Mains). It would also be advantageous to provide an A-UGV which can autonomously manage a tethered connection to an electrical outlet or receptacle, including managing the length of an electrical power cord extending between the A-UGV and the electrical outlet or receptacle. Other and further objects and advantages will appear hereinafter.

The present invention is directed to an apparatus and method for providing tethered electrical power to an A-UGV, and to an A-UGV and a method of operating an A-UGV which includes such an apparatus and executes such a method.

In one aspect of the invention, an autonomous unmanned ground vehicle (A-UGV) comprises: an electrical slip ring; a motor-driven cable reel disposed axially with respect to the electrical slip ring and configured to dispense and retract an electrical power cord, wherein the electrical power cord has a first end and a second end, and further has at the first end thereof an electrical plug for connection to an electrical socket supplying AC power, and wherein the second end thereof is electrically connected in series to the electrical slip ring; at least one sensor configured to produce sensor data in response to changes in a rotational position of the motor-driven cable reel; at least one processor, configured to receive the sensor data indicative of the rotational position of the motor-driven cable reel as feedback for commands sent by the at least one processor to the motor-driven cable reel so as to control a length of the electrical power cord which is dispensed by the motor-driven cable reel; at least one guide roller, the guide roller disposed such that it is axially parallel to the motor-driven cable reel, wherein the guide roller is configured to exert a force that presses an outermost layer of the electrical power cord against either an adjacent layer of the electrical power cord which is wound around the motor-driven cable reel, or against the motor-driven cable reel itself; and a level wind assembly, wherein the level wind assembly is configured to provide transverse movement along an axis parallel to an axis of the motor-driven cable reel, for controlling the winding, and unwinding, of the electrical power cord around the motor-driven cable reel.

In another aspect of the invention, a method is provided for operating an autonomous unmanned ground vehicle (A-UGV) configured with a robotic arm and an electrical power cord having an electrical plug at an end thereof and configured to be wound around a motor-driven electrical cord reel. The method comprises: while the location of an electrical outlet receptacle is within a work envelope of the robotic arm, controlling the robotic arm to grasp the electrical plug and then inserting the electrical plug into an electrical outlet; and while the electrical plug is being grasped by the robotic arm, controlling a length of the electrical power cord which is dispensed from the motor-driven electrical cord reel and a rate of dispensing the electrical power cord using kinematic data stored in one or more memory devices of the mobile robot, wherein one or more processors of the A-UGV employ the kinematic data to actuate one or more motors of the A-UGV which actuate the motor-driven electrical cord reel during a discrete computing event interval.

In yet another aspect of the invention, a method is provided for operating an A-UGV configured with an electrical power cord having an electrical plug at an end thereof and configured to be wound around a motor-driven electrical cord reel, The method comprises: while the electrical plug is connected to an electrical receptacle, controlling the A-UGV to move about; and while the electrical plug is connected to an electrical receptacle and the A-UGV moves about, controlling a length of the electrical power cord which is dispensed from the motor-driven electrical cord reel, and a rate of dispensing the electrical power cord, using odometric data stored in one or more memory devices of the A-UGV, wherein the odometric data is configured to cause one or more processors of the A-UGV to actuate one or more motors of the A-UGV which actuate the motor-driven electrical cord reel during a discrete computing event interval.

In a further aspect of the invention, a method is provided for operating an A-UGV configured with an electrical power cord having an electrical plug at an end thereof and configured to be wound around a motor-driven electrical cord reel. The method comprises: while the electrical plug is connected to an electrical receptacle, controlling the A-UGV to move about; and while the electrical plug is connected to an electrical receptacle and the A-UGV moves about, controlling a length of the electrical power cord which is dispensed from the motor-driven electrical cord reel and a rate of dispensing the electrical power cord using navigation instructions stored in one or more memory devices of the A-UGV, wherein the navigation instructions are configured to cause one or more processors of the A-UGV to actuate one or more motors of the A-UGV which actuate the motor-driven electrical cord reel during a discrete computing event interval.

### BRIEF DESCRIPTION OF THE DRAWINGS

FIG. 1 illustrates an embodiment of a system including an A-UGV.

FIG. 2 illustrates an embodiment of an A-UGV which is receiving electrical power from an electrical receptacle while moving about a room.

FIG. 3 illustrates an embodiment of a motorized level-wind AC electrical cord reel which dispenses an electrical power cord.

FIG. 4 illustrates a perspective view of the motorized level-wind AC electrical cord reel shown in FIG. 3.

FIG. 5 illustrates a perspective view of the motorized level-wind AC electrical cord reel shown in FIG. 3.

FIG. 6 illustrates a known embodiment of a rotary tensioner.

FIG. 7 illustrates an embodiment of a guide roller subassembly.

FIG. 8 illustrates a perspective view of the motorized level-wind AC electrical cord reel shown in FIG. 3.

FIG. 9 illustrates a known embodiment of an electrical slip ring.

FIG. 10 illustrates a sectional view of the motorized level-wind AC electrical cord reel shown in FIG. 3.

FIG. 11 illustrates an electrical schematic of an embodiment of a motorized level-wind AC electrical cord reel.

FIG. 12 illustrates a perspective view of a limit switch subassembly for detecting the position of the electrical cord plug from the motorized level-wind AC electrical cord reel shown in FIG. 3.

FIG. 13 illustrates a known robot arm.

FIG. 14 illustrates a sequence of steps for an example operation of an A-UGV which receives electrical power from a tethered connection to an electrical receptacle.

FIG. 15 is a flowchart of one embodiment of a method of navigation by an A-UGV which receives electrical power from a tethered connection to an electrical receptacle.

FIG. 16 is a drawing for explaining an example navigation of an A-UGV which receives electrical power from a tethered connection to an electrical receptacle.

FIG. 17 illustrates a sequence of steps in an example navigation operation of an A-UGV which receives electrical power from a tethered connection to an electrical receptacle and navigates a room or workspace.

FIG. 18 illustrates relevant components of an example process stack for one embodiment of a processor-controlled navigation system for an A-UGV.

### DETAILED DESCRIPTION

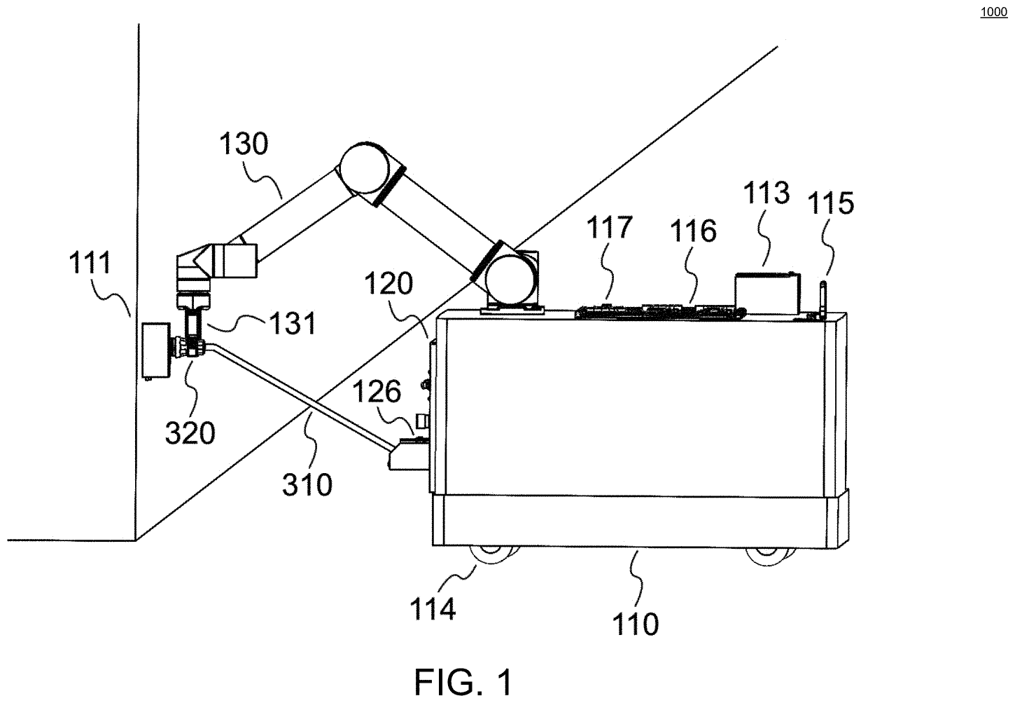

FIG. 1 illustrates an embodiment of a system 1000 including an A-UGV 110 which is plugged into an electrical receptacle 111. In some embodiments, A-UGV 110 may comprise a mobile robot. A-UGV 110 comprises a motor-driven electrical cord reel 120, a robot arm 130 including an end effectuator 131, a communications unit 115, a battery unit 113, a plurality of wheels 114, and a processor 116 with associated memory 117.

Although not depicted in FIG. 1, A-UGV 110 may also include one or more motors for controlling the movement of A-UGV 110 via wheels 114. Also not depicted in FIG. 1, A-UGV 110 may further include additional motors, arms, tools, and implements for performing one or more tasks that are assigned to A-UGV 110. In various embodiments, A-UGV 110 may be configured without a robotic arm 130. In other embodiments, A-UGV 110 may be configured to perform any number of different tasks, which may include but are not limited to vacuuming, sanding, grinding, scarifying, heating, welding, laser cutting, steaming, pressure washing, burnishing, sweeping, lifting and/or transporting objects, capturing images and/or audio, turning screws and/or bolts, fastening objects together, etc. Also not depicted in FIG. 1, A-UGV 110 may further include one or more sensors which are configured to sense the (linear) velocity of A-UGV 110 and/or robot arm 130 and/or end effectuator 131; the (linear) acceleration of A-UGV 110 and/or robot arm 130 and/or end effectuator 131; the rotational velocity of A-UGV 110 and/or robot arm 130 and/or end effectuator 131; and/or the rotational acceleration of A-UGV 110 and/or robot arm 130 and/or end effectuator 131.

In various embodiments, electrical receptacle 111 may include a household, commercial, or industrial electrical receptacle for supplying a standard voltage (e.g., 110 VAC, 220 VAC, 480 VAC, 3-Phase, etc.) from AC Mains.

As will be described in greater detail below, A-UGV 110 is able to autonomously locate, connect to and manage corded/tethered wire electrical connections to various electrical receptacles (e.g., electrical receptacle 111) as A-UGV 110 moves about a workspace to accomplish one or more tasks to which it has been assigned or programmed. The workspace may comprise one or more rooms, hallways, aisles, warehouses, factory(ies), etc.

In various embodiments, communications unit 115 may include a wireless communication device and/or a non-wireless communications port. In some embodiments, communications unit 115 may include a radio frequency (RF) communications device or a microwave communications device, and may include a communications transmitter, a communications receiver, and an antenna or antenna array, which in some embodiments may include a directional antenna. In various embodiments, the wireless communication device may communicate at various frequencies, for example 433 MHz, 900 MHz, 1.2 GHz, or 2.4 GHz, and may communicate using one or more standard communication protocols, such as WiFi, Bluetooth, 4G/LTE, 5G, etc.

In various embodiments, communications unit 115 may comprise various types of antennas, for example an Adcock antenna array, a quasi-Adcock array using multiple chips and antenna elements, a rotating dish, horn or Yagi antenna, or a steerable phased array antenna.

In some embodiments, communications unit 115 may include one or more communication ports, which may include one or more universal serial bus (USB) ports, firewire ports, CAN-BUS, RS-485, RS-232 and/or RJ-45 ports, and/or bespoke communication interface(s).

As described in greater detail below, in various embodiments communications unit 115 may be employed to facilitate identification and location of electrical receptacles 111 as A-UGV 110 operates within a particular workspace. In some embodiments, operational data regarding an autonomous operation to be performed by A-UGV 110 may be received by A-UGV 110 via communications unit 115. In some embodiments, this operational data may include work plan data defining a plan of work or tasks to be executed by A-UGV 110, and/or navigation plan data defining a navigation path to be traversed by A-UGV 110 as it performs the assigned tasks and/or odometric data from remote sensors as A-UGV 110 moves around the environment. In some embodiments, A-UGV 110 may receive software and/or firmware updates for processor 116 via communication unit 115.

Battery unit 113 may supply power for operation of A-UGV 110 when A-UGV 110 is not tethered to an electrical power source via electrical power cord 310. In some embodiments, battery unit 113 may be capable of supplying sufficient power for the operation of processor 116 and the motors which operate wheels 114 for a limited time so that A-UGV 110 may operate and navigate in between times when A-UGV 110 is connected to an electrical receptacle 111. Battery unit 113 may comprise rechargeable batteries which may be charged by electrical power received via electrical power cord 310 using a battery charger, and optionally a power conditioner, which may be included in battery unit 113.

As noted above, A-UGV 110 may include one or more motors which may operate wheels 114 so that A-UGV 110 may move throughout a workspace. In various embodiments, these motors may be supplied power by battery unit 113 and/or from a tethered connection to electrical receptacle 111 via electrical power cord 310. In some embodiments, these motors may receive power from battery unit 113 alone when A-UGV is not connected to an electrical receptacle 111.

In other embodiments, in addition to or in place of wheels 114, an A-UGV may move via wheels, rollers, continuous tracks, mechanical legs (e.g., a biped, quadruped, hexapod, etc.) or other locomotion means which allow them to navigate within a workspace such as an apartment, a factory, a warehouse, etc.

Processor 116 may control one or more operations of A-UGV 110. In various embodiments, processor 116 may control operations of robot arm 130, end effectuator 131, motor-driven electrical cord reel 120, communications unit 115, and/or one or more motors which operate wheels 114.

In some alternative embodiments, A-UGV 110 may include a plurality of processors, each of which may control one or more different operations of A-UGV 110. For example, A-UGV 110 may include a first processor for controlling operations of robot arm 130, a second processor for controlling operations of end effectuator 131, a third processor for controlling operations of motor-driven electrical cord reel 120, a fourth processor for controlling operations of communications unit 115, a fifth processor for controlling operations of the one or more motors which operate wheels 114, etc. In some embodiments, these processors may communicate with each other and share data to perform their various operations. It should be understood that processing power within A-UGV 110 may be distributed in a variety of manners in different embodiments.

The memory 117 associated with processor 116 may include volatile memory such as random access memory (RAM) and/or non-volatile memory such as read only memory (ROM), programmable read only memory (PROM), FLASH memory, etc.

FIG. 1 illustrates an embodiment of an electrical plug 320 for an electrical cord, and an end effectuator 131 of a robot arm 130 for an A-UGV 110.

Robot arm 130 is controlled in response to one or more control signals generated by a processor (e.g., processor 116) to selectively grasp, move, rotate, and release electrical plug 320 so as to align and connect electrical plug 320 to an appropriate electrical receptacle (e.g., electrical receptacle 111), and to disconnect electrical plug 320 from electrical receptacle 111. Although not depicted in FIG. 1, A-UGV 110 may also include one or more sensors to provide feedback and allow A-UGV 110 to control robot arm 130 and end effectuator 131 to selectively grasp, move, rotate, and release electrical plug 320.

In some embodiments, sensors may include an array of infrared (IR) sensors which are configured to provide sensor data which may be used by a processor (e.g., processor 116) which controls movements of a robot arm (e.g., robot arm 130) which includes end effectuator 131 so as to properly align and dock electrical plug 320 with the electrical receptacle 111. That is, in these embodiments the sensor data may indicate the position and alignment of an electrical receptacle 111 with respect to end effectuator 131.

In other embodiments, these sensors may comprise an array of video cameras which are configured to provide data which may be used by a processor (e.g., processor 116) which controls movements of a robot arm (e.g., robot arm 130) which includes end effectuator 131 so as to properly align and connect electrical plug 320 with the electrical receptacle 111. That is, in these embodiments the camera data may indicate the position and alignment of an electrical receptacle 111 with respect to end effectuator 131.

In other embodiments, these sensors may comprise an array of radar antennas which are configured to provide data which may be used by a processor (e.g., processor 116) which controls movements of a robot arm (e.g., robot arm 130) which includes end effectuator 131 so as to properly align and connect electrical plug 320 with the electrical receptacle 111. That is, in these embodiments the radar data may indicate the position and alignment of an electrical receptacle 111 with respect to end effectuator 131.

In some embodiments, end effectuator 131 is configured to connect electrical plug 320 into an electrical receptacle 111 in response to one or more signals (e.g., one or more acoustic signals) produced by electrical receptacle 111 and received by the one or more sensors.

In some embodiments, end effectuator 131 operates in response to a processor (e.g., processor 116) which may control end effectuator 131 at least in part in response to sensor data which indicates the position and alignment of an electrical receptacle 111 with respect to end effectuator 131.

In some embodiments, end effectuator 131 operates in response to a processor (e.g., processor 116) which may control end effectuator 131 using image based visual servoing (IBVMS) algorithms and methods.

As described in greater detail below, robot arm 130 and an associated processor (which may be a dedicated processor for robot arm 130, or may be a master processor 116 for A-UGV 110) provide a means for supplying tethered electrical power to A-UGV 110. In particular, in some embodiments A-UGV 110 may autonomously: locate a first electrical receptacle 111; navigate towards electrical receptacle 111 until electrical receptacle 111 is within the work envelope of robot arm 130; employ end effectuator 131 to plug the electrical plug 320 which is connected to electrical power cord 310 into the first electrical receptacle 111; manage the length of electrical power cord 310 as A-UGV 110 moves about a work area to perform all or a portion of one or more tasks assigned to it while electrical power cord 310 receives electrical power from the first electrical receptacle 111; determine when all or the portion of the one or more tasks assigned to A-UGV 110 which it is possible to complete given the location of the first electrical receptacle 111, and maximum length of the electrical power cord 310, has/have been completed; determine that electrical power cord 310 should be connected to a second electrical receptacle 111 in order to complete further portions of the one or more tasks assigned to A-UGV 110; return to the first electrical receptacle 111; disconnect electrical plug 320 from electrical receptacle 111; locate a second electrical receptacle 111; navigate towards the second electrical receptacle 111 until the second electrical receptacle 111 is within the work envelope of robot arm 130; employ end effectuator 131 to plug the electrical plug 320 which is connected to electrical power cord 310 into the second electrical receptacle 111; etc.

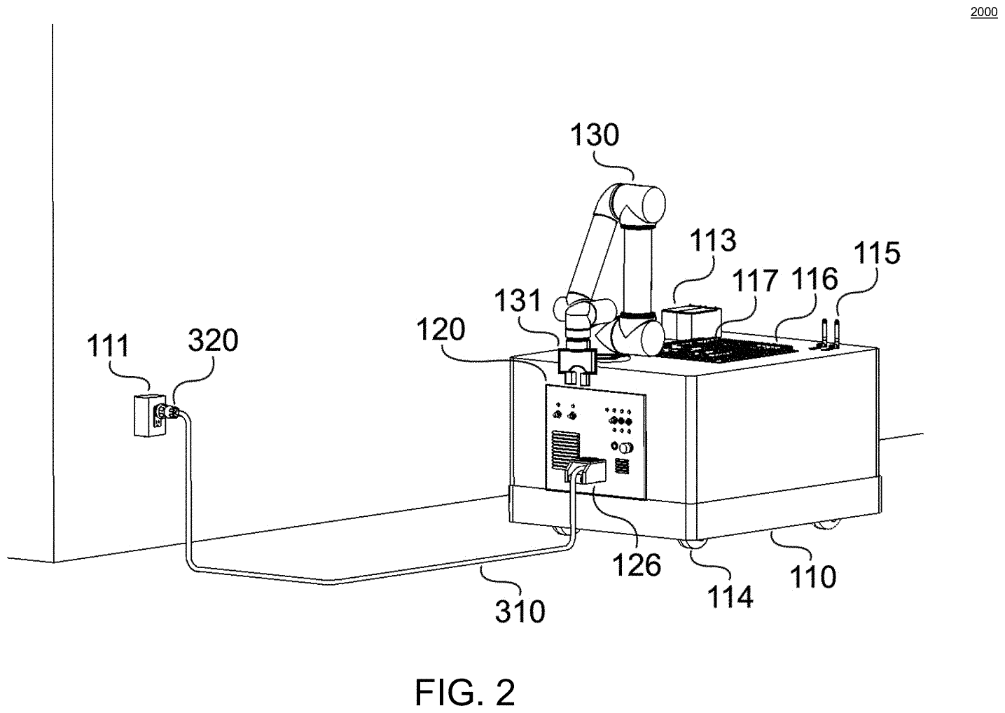

FIG. 2 illustrates an embodiment of an A-UGV 110 which is receiving electrical power from an electrical receptacle 111 while moving about a room 2000. As illustrated in FIG. 2, A-UGV 110 includes robot arm 130 having end effectuator 131, and the electrical power cord 310 having the electrical plug 320 at an end thereof. As illustrated in FIG. 2, electrical plug 320 is electrically connected to electrical receptacle 111 while A-UGV 110 moves about room 2000, and supplies electrical power to A-UGV 110 via electrical power cord 310.

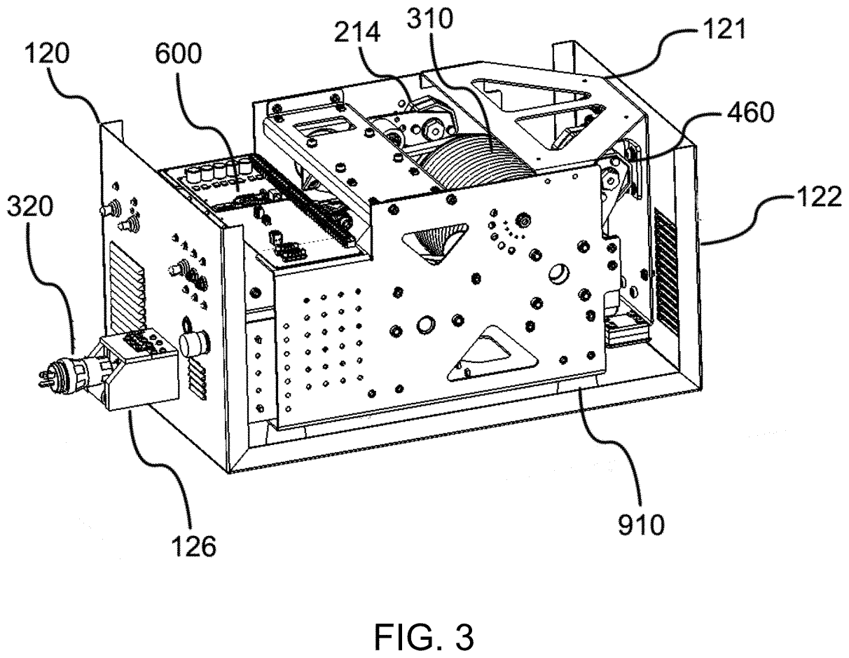

FIG. 3 illustrates an embodiment of a motor-driven electrical cord reel 120 which includes a structural chassis 121, a shell 122, a fairlead 126, the electrical cord 310, the electrical plug 320, a dedicated processor 600, and vibration dampening mounts 910.

In various embodiments, structural chassis 121 may be comprised of bent sheet metal, water formed sheet metal, welded sheet metal, riveted sheet metal, metal framing or formed composite elements designed to provide motor-driven electrical cord reel 120 with a rigid structure with which to attach the mechanical and/or electrical elements of motor-driven electrical cord reel 120.

In various embodiments, vibration dampening mounts 910 may be comprised of springs, dashpots, shock absorbers, vibration isolation pads, or visco-elastic elements designed to isolate and or dampen motor-driven electrical cord reel 120 from the vibrational oscillations A-UGV 110 is subjected to.

In various embodiments, motor-driven electrical cord reel 120 may have a fairlead 126 comprised of a variety of rollers, springs, brushes and bumpers that guide the electrical power cord 310 as well as clean the electrical power cord 310 so as to prevent dust ingress into motor-driven electrical cord reel 120.

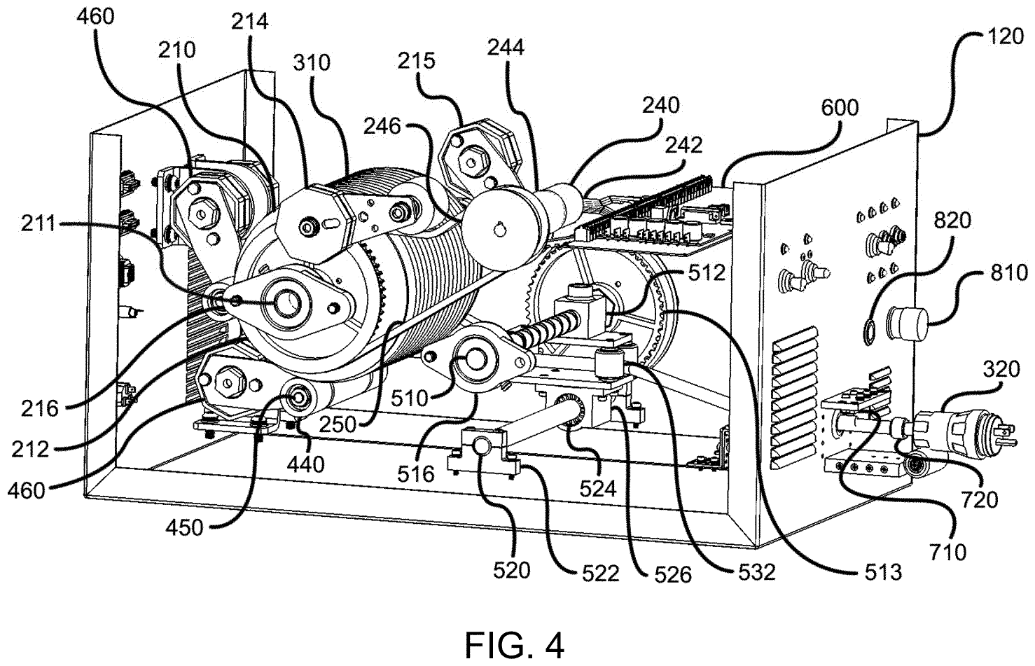

FIG. 4 illustrates an embodiment of a motor-driven electrical cord reel 120 which may be employed as motor-driven electrical cord reel 120 for A-UGV 110 in FIG. 1.

Motor-driven electrical cord reel 120 includes a cable reel 210, a motor 240, a sensor 242 (e.g., a motor rotational sensor) configured to produce electrical signals in response to changes in the rotational position of the cable reel 210, and a motor gearbox 244.

In various embodiments, cable reel 210 may include a grooved or smooth surface for the purpose of guiding the winding of the first layer of electrical power cord 310 around the cable reel 210. In various embodiments cable reel 210 may include an outer rim, ridge or flange at each end thereof for preventing the electrical power cord from coming off of either end of cable reel 210.

In various embodiments, motor 240 may be a brushless DC motor, a brushed DC motor, or a servo motor.

In other embodiments, sensor 242 may be a hall sensor, an optical rotary encoder, a magnetic rotary encoder, an absolute encoder or an incremental encoder.

In some embodiments, sensor 242 may be disposed along the axis of motor 240, in other embodiments, sensor 242 may be disposed along the axis of the cable reel 210.

In the embodiment illustrated in FIG. 4, motor-driven electrical cord reel 120 further includes a processor 600 configured to control the amount of electrical current sent to the motor 240, receive the electrical signal(s) produced by sensor 242, and to utilize that data as feedback for the control of the motor 240. In alternative embodiments, motor-driven electrical cord reel 120 may contain one or more processors to process the feedback data produced by sensor 242, or A-UGV 110 may centralize all processing on one central processor 116.

FIG. 4 further illustrates an embodiment of a motor-driven electrical cord reel 120 that includes a belt-drive comprising a cable reel driver pulley 246, a driven pulley 212, and belt 250.

Motor-driven electrical cord reel 120 may also include one or more belt tensioners 214 & 215 which are configured to eliminate slack in the portion of belt 250 and belt 251 (described below), respectively, as they are disposed on one or more pulleys. In alternative embodiments, belt tensioners 214 & 215 may consist of spring-loaded rotary tensioners, elastomeric rotary tensioners, spring loaded linear tensioners, fixed rollers, hydraulic tensioners or pneumatic tensioners.

Motor-driven electrical cord reel 120 utilizes a belt drive configuration, but it should be understood that in other embodiments, motor-driven electrical cord reels may employ chain drives, direct motor drives, gear drives and dual motor drives.

Motor-driven electrical cord reel 120 is configured to dispense and retract electrical power cord 310 so as to control a length thereof as the A-UGV navigates throughout a workspace, for example according to odometric data stored in a memory of the A-UGV.

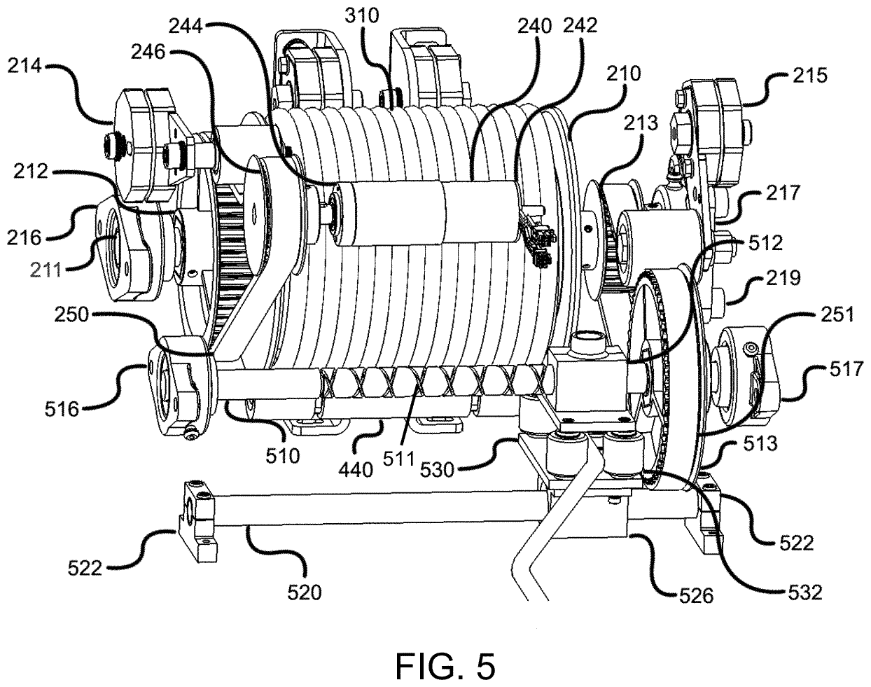

FIG. 5 illustrates an embodiment of a motor-driven electrical cord reel 120 which includes a level-wind mechanism for providing transverse motion for winding the electrical power cord 310 onto the cable reel 210. The level wind mechanism comprises a machined diamond screw 510, a pawl and housing 512, a driver pulley 213, a driven pulley 513, a belt 251, a set of bearings 516 & 517, a linear shaft 520 mounted to chassis 121 by shaft mounts 522, a linear bearing housing 526 for linear bearing 524 (see FIG. 4), and cord guide assembly 530 consisting of one or more rollers 532. Also shown in FIG. 5 are starboard-side cable reel shaft bearing spacers 219. Diamond screw 510 has grooves 511 etched therein, typically only in a central portion thereof, for engaging with ridges in cable reel 210. In some embodiments, diamond screw 510 is either steel or stainless steel. Furthermore, in some embodiments diamond screw 510 has a rather large diameter (e.g., about one inch in diameter). This may make diamond screw 510 one of the heaviest components in the reel assembly. The depth of grooves 511 may preclude using diamond screw 510 having a hollow shaft, but, in the area to the left and the right of grooves 511, an interior of diamond screw 510 may be bored out to lessen the weight of diamond screw 510, with little to no cost penalty in terms of strength or durability.

In various embodiments, the transverse motion of the cord guide assembly 530 may be powered by a 2^{nd} motor. In other embodiments, the rotation of diamond screw 510 may be powered by chain or gear driven drives.

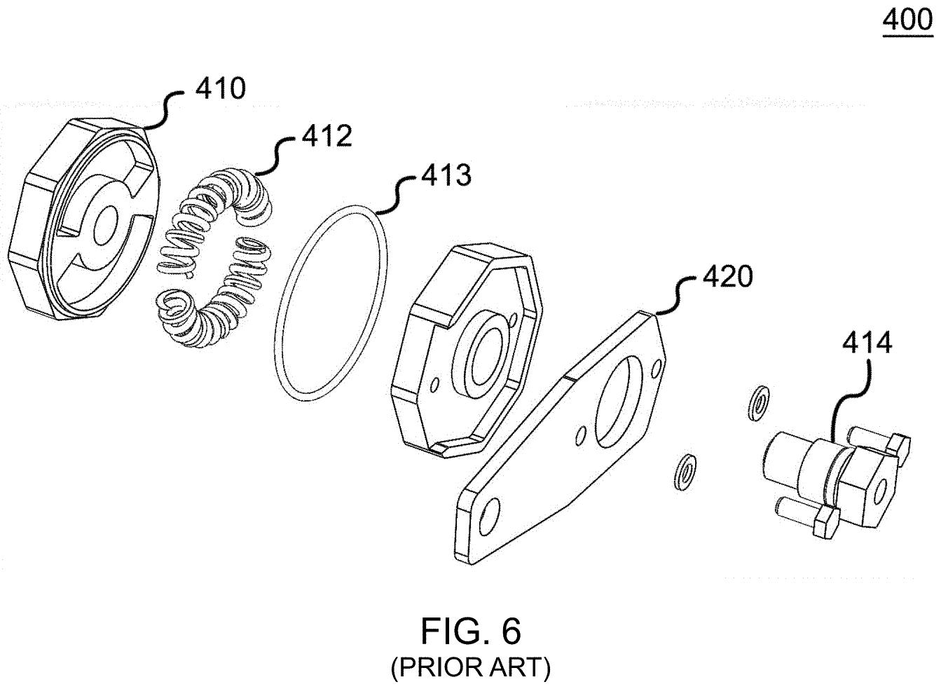

FIG. 6 illustrates a known rotary tensioner 400. Rotary tensioner 400 comprises a housing 410 which contains one or more compression springs 412, an O-ring 413, a lever arm 420, and a shaft 414 that allows rotary tensioner 400 to exert a force against an object.

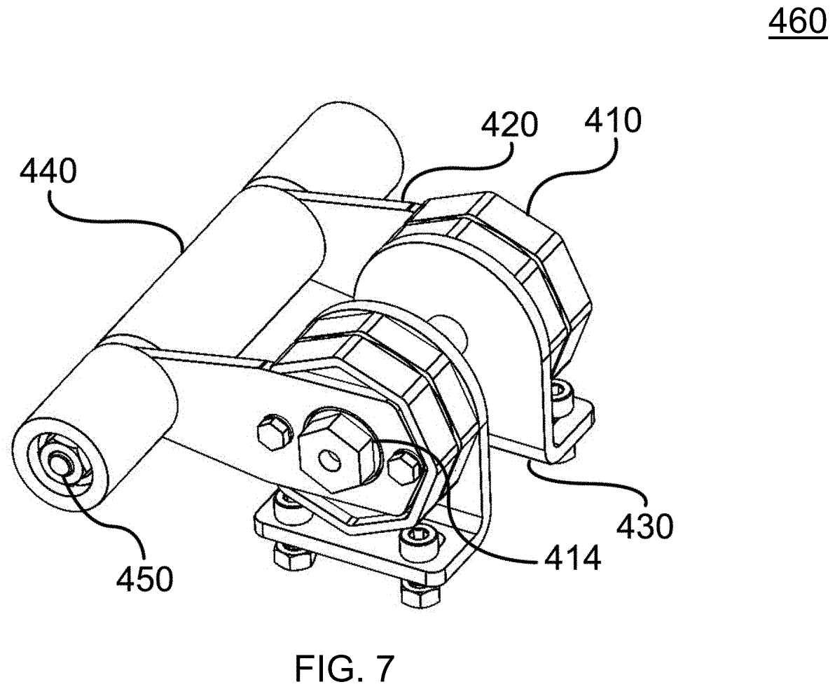

FIG. 7 illustrates an embodiment of a spring-loaded guide roller subassembly 460 which includes rotary tensioner 400 comprising housing 410 and lever arm 420, one or more mounting brackets 430, one or more guide rollers 440, and a roller shaft 450.

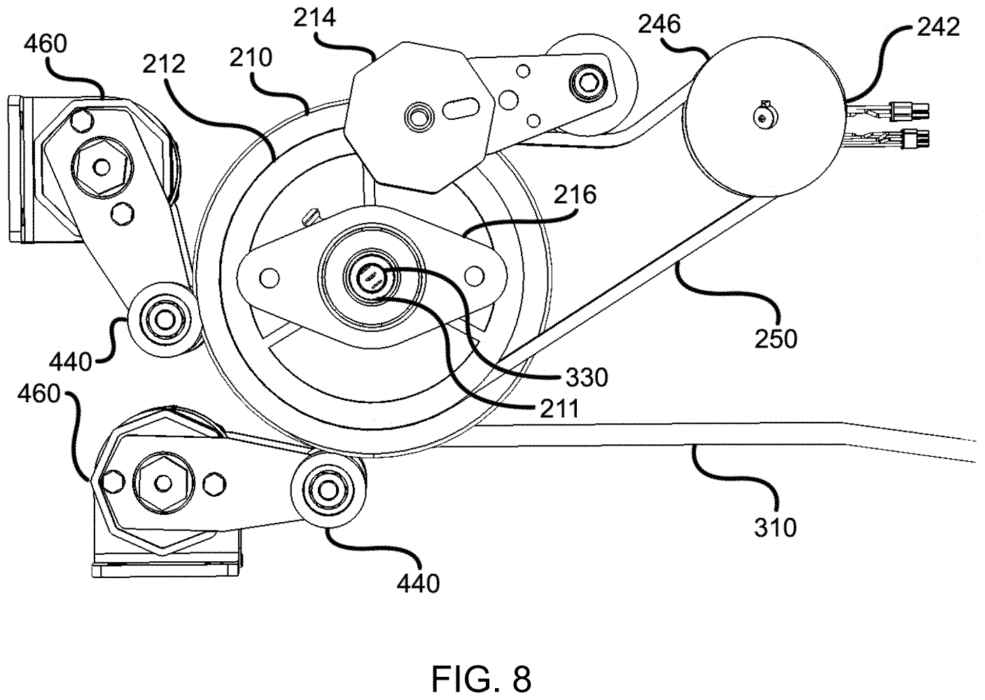

FIG. 8 illustrates a side-perspective view of an embodiment of a spring-loaded guide roller subassembly 460 which includes housing 410, lever arm 420, one or more mounting brackets 430, one or more guide rollers 440, and roller shaft 450.

Motor-driven electrical cord reel 120 may also include one or more guide rollers 440 which are configured to press the outermost layer of electrical cord 310 into the previous layer of electrical cord 310 disposed on cable reel 210 or into cable reel 210 itself, and thereby prevent the electrical cord 310 from lifting off the back of the cable reel 210, particularly while motor-driven electrical cord reel 120 is dispensing electrical cord 310.

In alternative embodiments, spring-loaded guide roller subassembly 460 may consist of spring-loaded rotary tensioners, elastomeric rotary tensioners, spring loaded linear tensioners, fixed rollers, hydraulic tensioners or pneumatic tensioners.

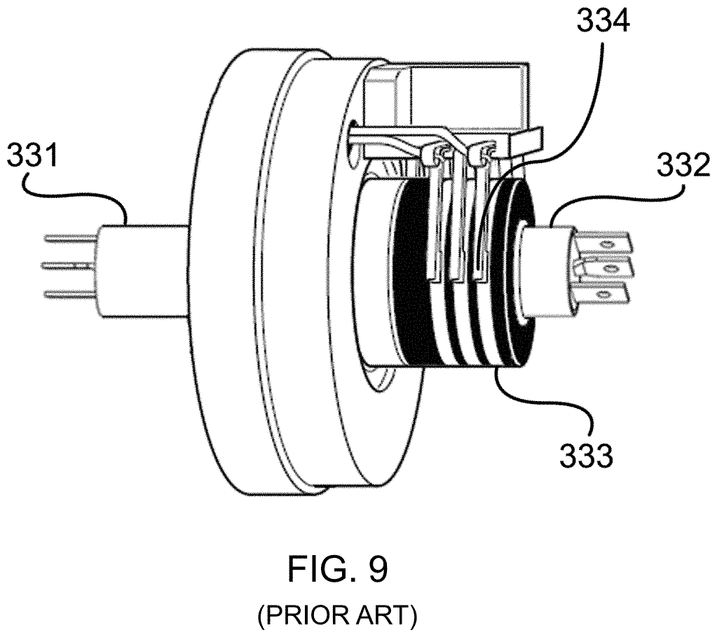

FIG. 9 illustrates a known electrical slip ring. Slip rings are electromechanical devices that allow for the transmission of power and electrical signals from stationary to rotating structures and are utilized in systems that rotate while transmitting power and/or data.

An electrical slip ring is comprised of at least two sets of electrical leads, the first set attached to a non-rotating stator 331, and the second set attached to a freely rotating rotor 332. The electrical connection between the stationary and rotating parts is maintained by the contact between the conductive rings disposed on the rotor 333 and the electrical brushes disposed on the stator 334.

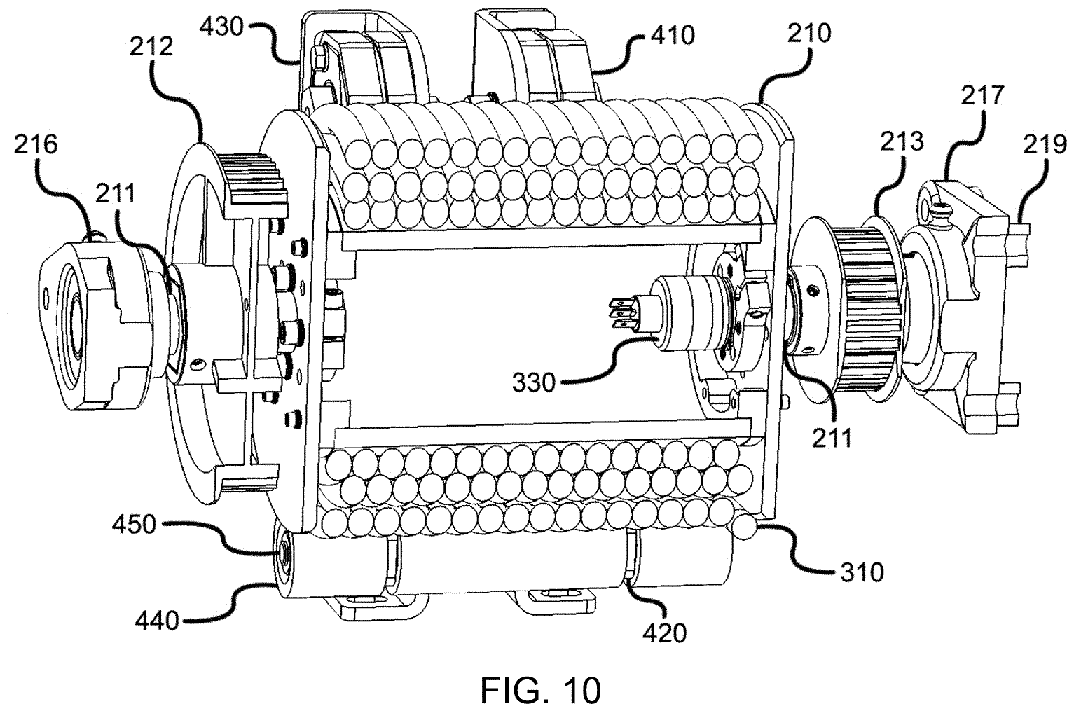

FIG. 10 illustrates an embodiment of cable reel 210 which includes an electrical slip ring 330, electrical power cord 310, one or more drive pulleys 212 & 213, one or more cable reel shafts 211, and bearings 216 & 217.

In various embodiments, electrical slip ring 330 may be disposed outside of cable reel 210.

In other embodiments, electrical power cord 310, electrical plug 320 and electrical slip ring 330 may be configured to include additional electrical leads and wires that allow for additional power or data circuits.

In various embodiments, electrical plug 320 may have a variety of configurations, including two-prong, three-prong, with or without a ground prong, etc. In various embodiments, cable reel shaft 211 may be hollow to provide a path for one or more electrical leads.

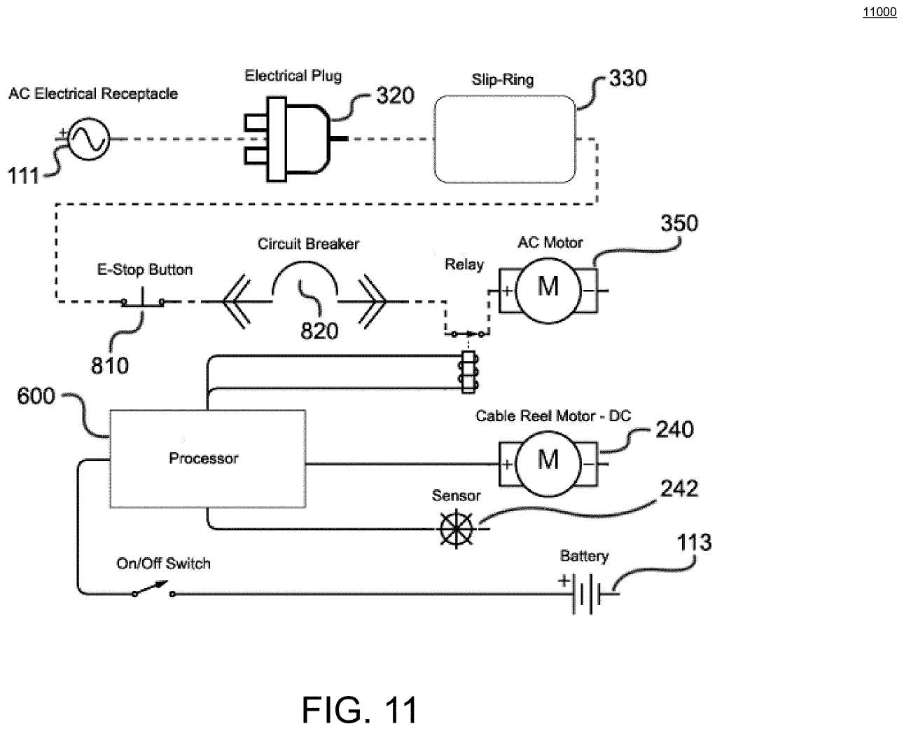

FIG. 11 shows an electrical schematic for one embodiment of a system 11000 for supplying tethered electrical power to A-UGV 110. System 11000 may be one embodiment of system 1000 illustrated in FIG. 1. As illustrated in FIG. 11, system 11000 includes electrical receptacle 111, electrical plug 320, electrical slip ring 330, an emergency stop button 810, a circuit breaker 820, a relay and an AC electrical motor 350. In addition to the AC electrical circuit described above, system 11000 also includes battery 113, an on/off switch, processor 600, motor (e.g., DC electrical motor) 240, and sensor (e.g., motor rotational sensor) 242.

In some embodiments, the elements of the electrical circuits shown in FIG. 11 may be connected in a different order. In other embodiments, the AC circuit may be connected to an AC/DC power converter and AC electrical 410 motor 350 may be replaced with a DC motor.

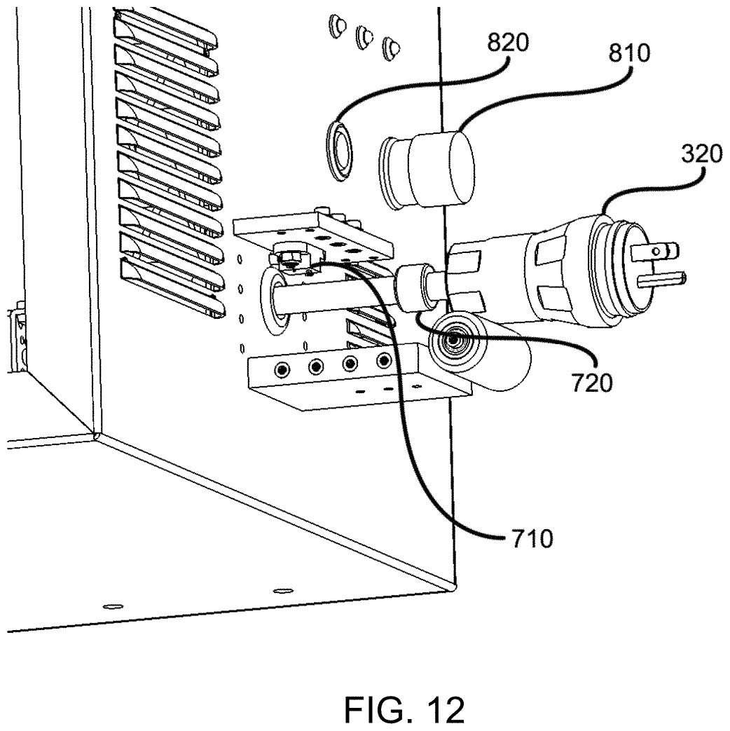

FIG. 12 illustrates an embodiment of a motor-driven electrical cord reel 120 which includes a limit switch comprising a sensor 710 and a ring magnet 720 disposed near the distal end of electrical power cord 310, and electrical plug 320. The limit switch is configured to produce an electrical signal in response to the proximity of ring magnet 720 to the sensor 710 and thereby serve as a calibration signal that electrical power cord 310 is fully retracted.

In various embodiments, sensor 710 may consist of a hall sensor, reed sensor, IR proximity sensor, acoustic transducer, or video camera.

FIG. 12 further illustrates an embodiment of a motor-driven electrical cord reel 120 which includes an emergency stop button 810 configured to sever an electrical connection in response to a user pressing the emergency stop button.

In some embodiments, emergency stop button 810 may sever the AC power circuit formed when electrical plug 320 is connected to electrical receptacle 111, in response to a user pressing the emergency stop button.

In other embodiments, emergency stop button 810 may sever the DC electrical power circuit between battery 113 and motor (e.g., DC electrical motor) 240 in response to a user pressing the emergency stop button.

In other embodiments, emergency stop button 810 may sever the AC power circuit formed when electrical plug 320 was connected to electrical receptacle 111 and sever the DC electrical power circuit between battery 113 and motor (e.g., DC electrical motor) 240 in response to a user pressing the emergency stop button.

FIG. 12 further illustrates an embodiment of motor-driven electrical cord reel 120 which includes a circuit breaker 820 configured to sever an electrical connection in response to the electrical current flowing through that circuit exceeding a certain specified threshold.

In some embodiments, circuit breaker 820 may sever the AC power circuit formed when electrical plug 320 is connected to electrical receptacle 111, in response to the electrical current flowing through that circuit exceeding a certain specified threshold.

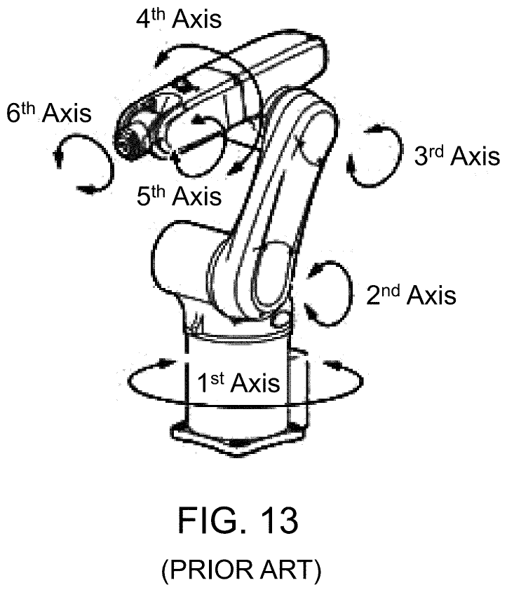

FIG. 13 illustrates a known robot arm 130. Beneficially, robot arm 130 may be a six axis robot arm, which is a current “gold standard” for industrial robotic arms. In that case, robot arm 130 has six axes of motion, produced by six joints, including three cylindrical axes (e.g., axes 1, 4 & 6) and three revolute axes (e.g. 2, 3 & 5).

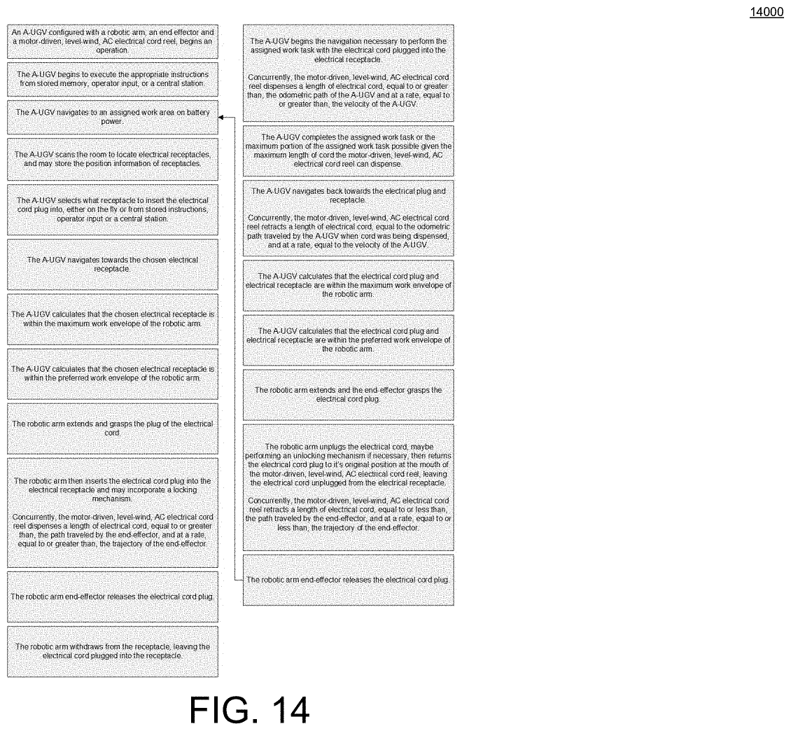

FIG. 14 illustrates a sequence of steps for an example operation 14000 of an A-UGV which receives electrical power from a tethered connection to an electrical receptacle. In particular, FIG. 14 illustrates an operation 14000 wherein the A-UGV moves throughout a workspace according to a navigation plan to perform assigned work tasks, connecting and disconnecting with various electrical receptacles as necessary. In some embodiments, the A-UGV may be A-UGV 110 of FIG. 1. The detailed steps of operation 14000 as shown in FIG. 14 are self-explanatory and will not be repeated here in the interest of brevity.

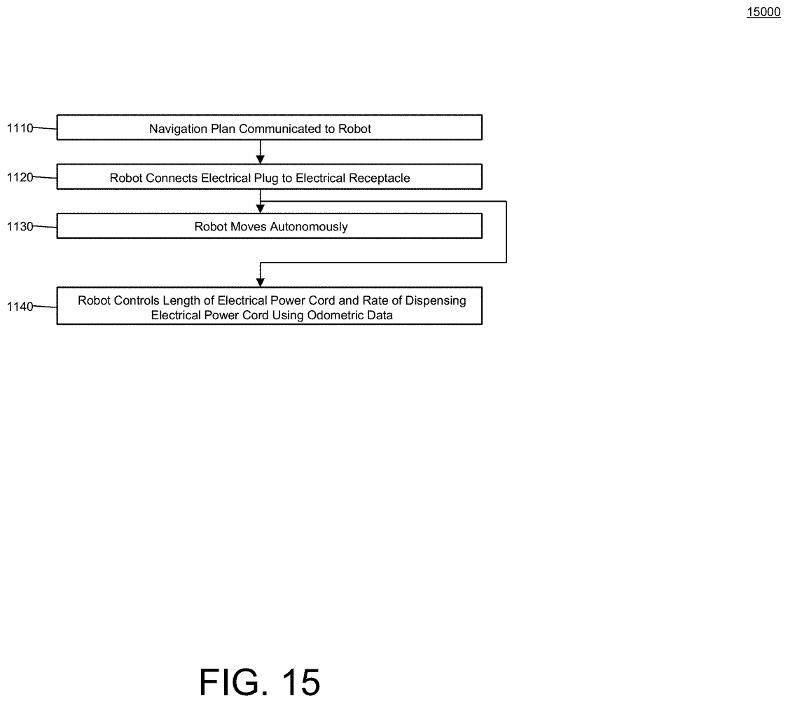

FIG. 15 is a flowchart of another embodiment of a method 15000 of navigation by an A-UGV which receives electrical power from a tethered connection to an electrical receptacle. In particular, method 15000 represents an example embodiment of a method whereby an A-UGV navigates throughout a given area such as a room or workspace according to a navigation plan.

In a first step 1110, the navigation plan is communicated to the A-UGV. The navigation plan may be represented by navigation instructions which may be stored in a memory device in the A-UGV and accessed by a processor which controls one or more operations of the A-UGV. In some embodiments, the navigation instructions may be communicated to the A-UGV via a communications device of the A-UGV. Such communication may be done wirelessly or via a wired connection.

In some embodiments, the navigation instructions are configured to cause one or more processors of the A-UGV to actuate one or more motors of the A-UGV which move the A-UGV with respect to some fixed point in relation to the electrical receptacle during at least one of a discrete time interval and an event interval. Here, an event is an action or occurrence detected by a program running on a processor of the A-UGV, and may include inputs from hardware such as sensors and communication devices, as well as software instructions, messages and returned values from program subroutines.

In a step 1120, the A-UGV connects an electrical plug of an electrical power cord of the A-UGV to an electrical receptacle, in a room or workspace where the A-UGV is to perform one or more tasks. The connection may be made via a robot arm having an end effector as described in greater detail above.

In a step 1130, the A-UGV moves autonomously through the room or work space, performing its assigned tasks, while receiving tethered electrical power from the electrical receptacle. In various embodiments, the A-UGV may move via wheels, rollers, continuous tracks, mechanical legs (e.g., a biped, quadruped, hexapod, etc.) or other locomotion means which allow them to navigate within a workspace such as an apartment, a factory, a warehouse, etc.

In a step 1140, the A-UGV controls the length of an electrical power cord which it dispenses, and the rate of dispensing the electrical power cord, according to odometric data stored in a memory device in the A-UGV. In other embodiments, the length of electrical power cord released by motorized cable reel 210 may be calculated in advance by at least one processor that directly receives information from those computing processes that comprise the robot navigation instructions. In other embodiments, the length of electrical power cord and the rate of dispensing the electrical cord may be calculated using a navigation plan stored as navigation data in a memory device of the apparatus, the navigation plan describing a navigation path and speed to be traveled by the robot during a specified time and/or event interval.

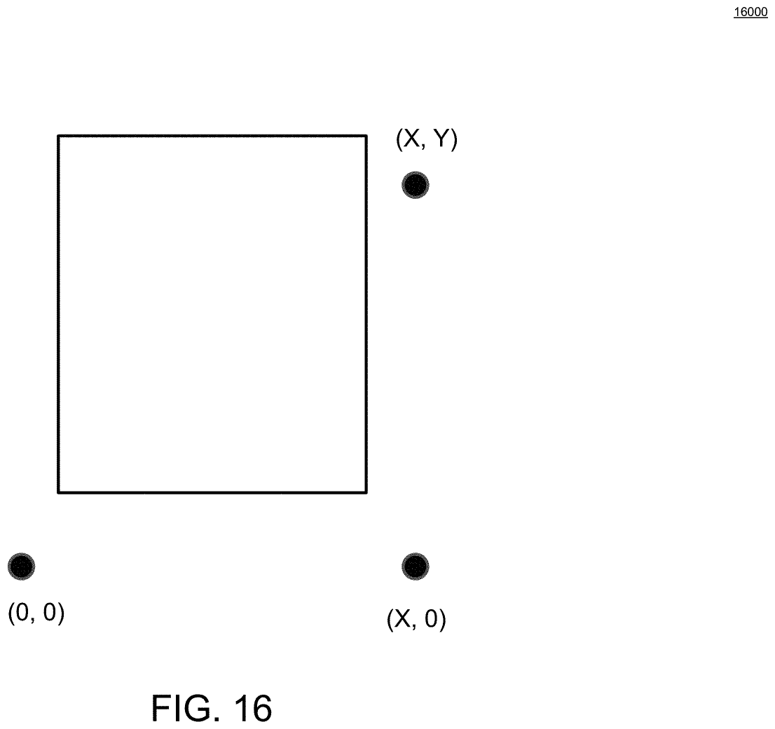

FIG. 16 is a drawing for explaining an example navigation of an A-UGV which receives electrical power from a tethered connection to an electrical receptacle. In particular, FIG. 16 illustrates a room or workspace 16000 which three specific locations labeled by corresponding coordinates (0, 0), (X, 0) and (X, Y).

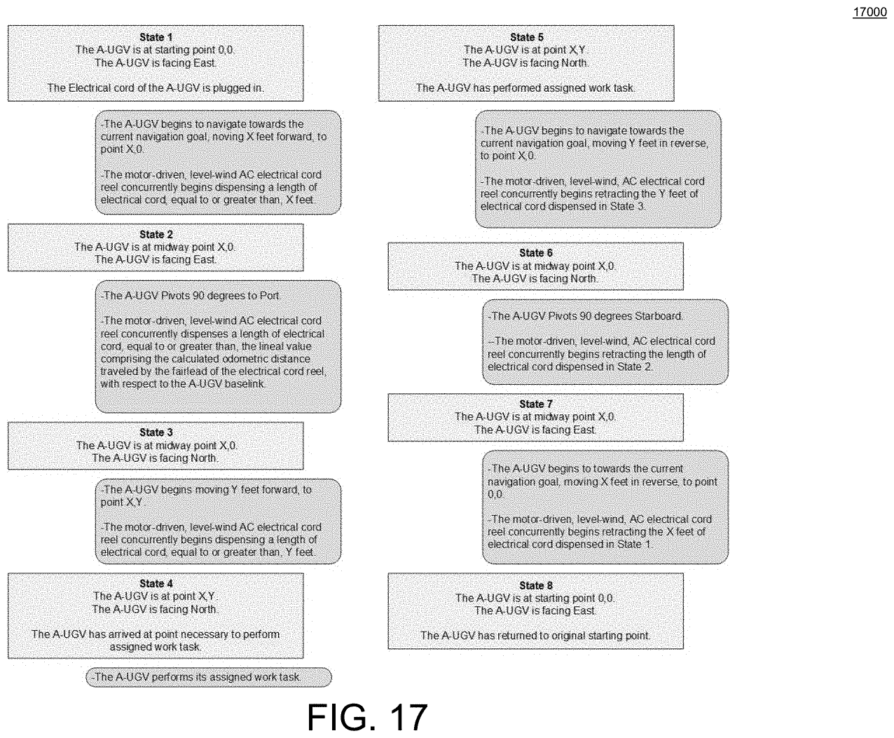

FIG. 17 illustrates a sequence of steps in an example navigation operation 17000 of an A-UGV which receives electrical power from a tethered connection to an electrical receptacle and navigates a room or workspace 16000. The detailed steps of operation 17000 as shown in FIG. 17 are self-explanatory and will not be repeated here in the interest of brevity.

In the descriptions to follow, the following definitions will be employed.

Process.

A process is a container for a set of resources used when executing an instance of a computer program. It comprises:
Allocated memory space;
An executable program, which defines initial code and data that is mapped into the memory space allocated for the process;
A list of descriptors to various system resources such as semaphores, communication ports, files, etc. (in UNIX terminology, these are known as descriptors, while in WINDOWS systems, these are called handles);
A unique ID.

Node (Software).

A node is a process executed in a distributed computing environment.

Plugin (Software)

A plugin is a piece of software code that requires an existing process to run. They are often used as a method to provide programmers with the capability to modify and extend application behavior without needing to modify the application source code.

Inter-Process Communication (IPC).

Inter-process communication (IPC) mechanisms enable processes to exchange data and synchronize execution. IPC may also be referred to as inter-thread communication. The main IPC methods are: message queue, signals, socket, pipe, named pipe, semaphore, and shared memory. In addition to IPC, POSIX threads have the following methods for synchronization: mutual exclusion (mutex) locks, condition variables, and read-write locks. Other forms of IPC include Java Remote Method Invocation (RMI), Common Object Request Broker Architecture (CORBA), Message Passing interface (MPI), QNX, Microsoft Message Queuing (MSMQ), XML-RPC, ONC-RPC, Synchronous Interprocess Messaging Project for Linux (SIMPL), Solaris Doors, and Windows Local Procedure Calls.

Synchronous Messaging.

A synchronous computing operation blocks a given process until a given operation completes. In the case of a message, both the send and receive operations complete when the sending process receives confirmation that the message has been delivered to the receiver. An example would be the case of remote procedure call, wherein the send, receive, and reply operations complete when the reception confirmation (the reply) has been delivered to the sender. Synchronous message passing systems require the sender and receiver to wait for each other to transfer the message. That is, the sending object will not continue until is has received confirmation that the receiving object has received the message.

Asynchronous Messaging.

An asynchronous computing operation is non-blocking and only initiates the operation. Asynchronous message passing allows more parallelism. Since a process does not block, it can continue to perform other operations while the message is in transit. In the case of receiving, this means a process can express its interest in receiving messages on multiple ports simultaneously. Asynchronous message passing systems deliver a message from sender to receiver, without waiting for the receiver to be ready. The advantage of asynchronous communication is that the sender and receiver can overlap their computing operations because they do not wait for each other.

Request-Reply Message Pattern.

The request-reply message pattern connects a set of clients to a set of services. Typically implemented in a synchronous fashion, for one-to-one communication between computer processes or applications

Publish-Subscribe Message Pattern.

The publish-subscribe message pattern connects a set of publishers to a set of subscribers. This is a one-to-many data distribution pattern, typically implemented in an asynchronous fashion.

With these definitions and understandings in mind, we now discuss embodiments of computing architectures for A-UGVs.

There exist a large variety of computing architecture possibilities for mobile robotics platforms. On one end of the spectrum there is the single processor architecture, which very similar to a personal computer, wherein the various parts of the robot are treated as devices and controlled by device drivers via an I/O manager. Moving on the spectrum from single to distributed computing architectures, we can imagine a computing cluster comprising a master “hardware node”, and a number of slave hardware nodes, each hardware node consisting of a processor with attached memory, the architecture communicating via a single system image middleware. On the far end of the distributed system spectrum we encounter a system of multiple peer hardware nodes, again tied together by middleware software that distributes computational tasks among the multiple processors. In both distributed computing configurations, it is likely that the middleware would be constructed in such a way as to provide a single system image, by abstracting the hardware details away to let the programmer focus on the software in isolation.

Robot Kinematics.

Forward kinematics is a branch of mathematics used in robotics to calculate the position of the end-effector from specified values for the joint parameters.

Inverse Kinematics is the branch of mathematics used in robotics to calculate the values of joint parameters that provide a desired position for a robot end-effector.

A point is a data structure that represents the position of a point in free space containing at least 3 values corresponding to the 3D coordinate values x,y,z.

A quaternion is a data structure that represents an orientation in free space.

A pose is a data structure that represents the position and orientation of a point in free space, usually comprised of a point and a quaternion.

A path is a data structure that represents a series of poses, usually comprised of an array of poses.

A trajectory is a data structure that specifies other values necessary to create a motion plan for a joint, or joints of a robotic arm. A trajectory is usually comprised of an array of points, and some combination of velocity, acceleration, effort and time data depending on the particular software implementation.

Kinematic data describes a family of data structures used describe the motion of mechanical systems composed of joined parts in 3D space, and includes data structures such as points, quaternions, poses, paths, and trajectories.

Odometry.

Odometry is the use of data from sensors to estimate the change in position of a body over time. In the field of robotics, it is often used to estimate the position of a robot relative to some reference position. It is one of the methods of robot localization.

Rotary encoders are often used in conjunction with motorized wheels to generate odometric data. Other sensor sources include GPS transceivers, video cameras, laser scanners, ultrasonic transducers, radar antennas, infrared proximity sensors and many more. Data from multiple sensor sources can be used in order provide more accurate and reliable odometric data.

Odometric data describes a family of data structures used describe the position of a mechanical system, relative to some reference position, and includes data structures such as points, quaternions, poses, paths, and velocity vectors.

Coordinate Frames

A robotic system typically has multiple 3D coordinate frames, but common frames include a world-frame that serves as a long term global reference for positioning, a base-frame that consists of a coordinate frame rigidly attached to an A-UGV, and map-frames that incorporate other geographic or stationary features.

Transforms are mathematical and computational tools that allow users to keep track of multiple coordinate frames over time by transforming the position coordinates of a first coordinate frame, to the position coordinates of a second coordinate frame.

For example, by performing transforms, it is possible to determine the position of an appendage to a mobile robot, as the robot moves over time, in relation to a feature on a map.

Regardless of the details pertaining to a specific embodiment, the length of electrical power cord released by the motorized cable reel, which is attached to a robot, may be calculated by at least one process that directly receives information, either directly or indirectly, from those computing processes that control the movement of the robot base and the robot arm, via a variety of messaging patterns and protocols that in various embodiments may include IPC mechanisms, and then by the operation of various algorithms, which in some embodiments include preconfigured data, to calculate the electrical power cord length to be dispensed and the rate of dispensation, and then dispense/retract the electrical power cord in synchronization with the movement of the robot and/or robot arm.

In any robot/A-UGV navigation system, there will be a number of running processes, being executed on either a single processor, or distributed among multiple processors.

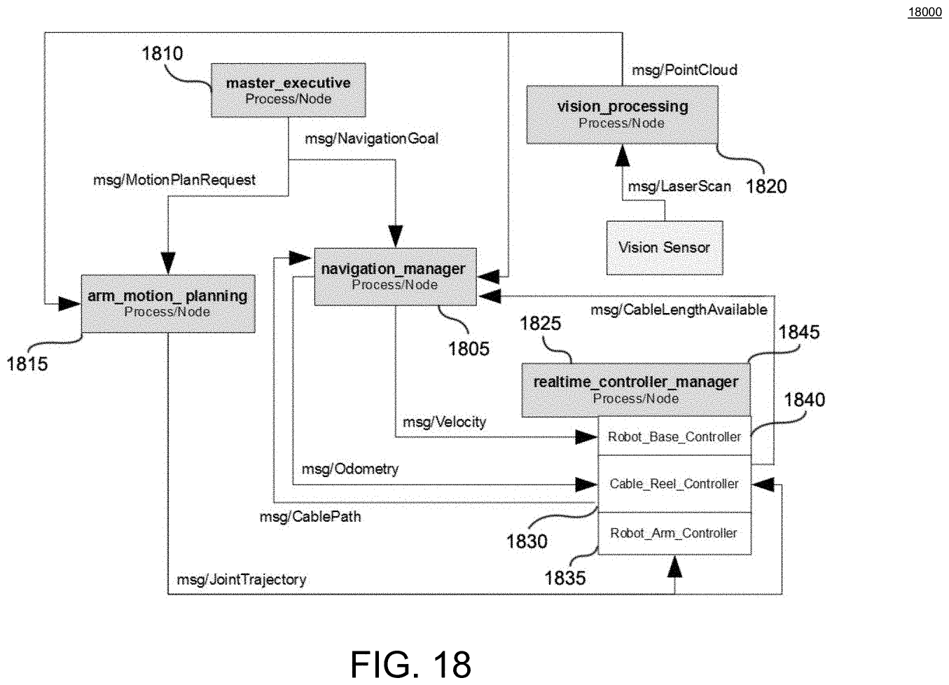

FIG. 18 illustrates relevant components of an example process stack 18000 for one embodiment of a processor-controlled navigation system for an A-UGV. In this embodiment, all communication between the processes shown consist of asynchronous messages broadcast in a publish-subscribe message pattern.

As illustrated in FIG. 18, a navigation_manager process 1805 receives messages published by a vision_processing process 1820, and master_executive process 1810, and subsequently publishes movement commands that are subscribed to by realtime_controller_manager process 1825, and its running software plugin Robot_Base_Controller 1840.

Robot_Base_Controller plugin 1840 performs the calculations necessary to transmit the movement commands into electrical pulses necessary to drive the electric motors used for locomotion of the A-UGV.

The Cable_Reel_Controller plugin 1830 calculates the length of electrical power cord that needs to be dispensed and the rate at which it needs to be dispensed based on the detected odometric movement engendered by Robot_Base_Controller plugin 1840.

Cable_Reel_Controller plugin 1830 publishes messages (e.g., msg/CableLengthAvailable) which communicate the length of electrical power cord available, and which are subscribed to by the navigation_manager process 1805; and messages (e.g., msg/CablePath) indicating the path of the electrical power cord, which are subscribed to by the navigation_manager process 1805, which incorporates the path of the electrical power cord into it's mapping of obstacles so as to prevent the A-UGV from running over the laid electrical power cord.

Other embodiments may include other sensors for detecting obstacles, and corresponding processes for providing messages to navigation_manager process 1805 to indicate the presence and/or location of an obstacle.

Other embodiments may use a variety of communication methods which could include a combination of synchronous and asynchronous messaging techniques over a variety of hardware and software architectures. On single processor systems, it is more likely that the specific embodiment would utilize IPC techniques, while in multi-processor systems, the robot would use messaging patterns and protocols specific to the middleware embodiment.

Other embodiments may include other processes in the navigation application such as error handling procedures, additional sensor control processes, frame transform calculations, etc.

While preferred embodiments are disclosed herein, many variations are possible which remain within the concept and scope of the invention. Such variations would become clear to one of ordinary skill in the art after inspection of the specification, drawings and claims herein. The invention therefore is not to be restricted except within the spirit and scope of the appended claims.

We claim:

1. A method of operating an autonomous unmanned ground vehicle (A-UGV) configured with a robotic arm and an electrical power cord having an electrical plug at an end thereof and configured to be wound around a motor-driven electrical cord reel, the method comprising:
while a location of an electrical outlet receptacle is within a work envelope of the robotic arm, controlling the robotic arm to grasp the electrical plug and then inserting the electrical plug into an electrical outlet; and
while the electrical plug is being grasped by the robotic arm, controlling a length of the electrical power cord which is dispensed from the motor-driven electrical cord reel and a rate of dispensing the electrical power cord using kinematic data stored in one or more memory devices of the A-UGV,
wherein one or more processors of the A-UGV employ the kinematic data to actuate one or more motors of the A-UGV which actuate the motor-driven electrical cord reel during a discrete computing event interval.

2. The method of claim 1, wherein the robotic arm includes one or more motors which employ the kinematic data to control movement of the robotic arm.

3. A method of operating an A-UGV configured with an electrical power cord having an electrical plug at an end thereof and configured to be wound around a motor-driven electrical cord reel, the method comprising:
while the electrical plug is connected to an electrical receptacle, controlling the A-UGV to move about; and
while the electrical plug is connected to the electrical receptacle and the A-UGV moves about, controlling a length of the electrical power cord which is dispensed from the motor-driven electrical cord reel, and a rate of dispensing the electrical power cord, using odometric data stored in one or more memory devices of the A-UGV,
wherein the odometric data is configured to cause one or more processors of the A-UGV to actuate one or more motors of the A-UGV which actuate the motor-driven electrical cord reel during a discrete computing event interval.

4. A method of operating an A-UGV configured with an electrical power cord having an electrical plug at an end thereof and configured to be wound around a motor-driven electrical cord reel, the method comprising:
while the electrical plug is connected to an electrical receptacle, controlling the A-UGV to move about; and
while the electrical plug is connected to the electrical receptacle and the A-UGV moves about, controlling a length of the electrical power cord which is dispensed from the motor-driven electrical cord reel and a rate of dispensing the electrical power cord using navigation instructions stored in one or more memory devices of the A-UGV,
wherein the navigation instructions are configured to cause one or more processors of the A-UGV to actuate one or more motors of the A-UGV which actuate the motor-driven electrical cord reel during a discrete computing event interval.

5. An autonomous unmanned ground vehicle (A-UGV) comprising:
an electrical slip ring;
a motor-driven cable reel disposed axially with respect to the electrical slip ring and configured to dispense and retract an electrical power cord, wherein the electrical power cord has a first end and a second end, and further has at the first end thereof an electrical plug for connection to an electrical socket supplying AC power, and wherein the second end thereof is electrically connected in series to the electrical slip ring;
at least one sensor configured to produce sensor data in response to changes in a rotational position of the motor-driven cable reel;
at least one processor, configured to receive the sensor data indicative of the rotational position of the motor-driven cable reel as feedback for commands sent by the at least one processor to the motor-driven cable reel so as to control a length of the electrical power cord which is dispensed by the motor-driven cable reel;
at least one guide roller, the guide roller disposed such that it is axially parallel to the motor-driven cable reel, wherein the guide roller is configured to exert a force that presses an outermost layer of the electrical power cord against either an adjacent layer of the electrical power cord which is wound around the motor-driven cable reel, or against the motor-driven cable reel itself; and
a level wind assembly, wherein the level wind assembly is configured to provide transverse movement along an axis parallel to an axis of the cable reel, for controlling the winding, and unwinding, of the electrical power cord around the cable reel.

6. The autonomous unmanned ground vehicle (A-UGV) of claim 5, further comprising a limit switch subassembly comprising at least one sensor configured to produce sensor data indicative of a proximity of at least one feature of the electrical power cord to the at least one sensor.

7. The autonomous unmanned ground vehicle (A-UGV) of claim 6, wherein the sensor is a Hall-effect sensor, and further comprising a magnet secured to the first end of the electrical power cord.

8. The autonomous unmanned ground vehicle (A-UGV) of claim 5, further comprising an emergency stop button configured to sever an AC electrical connection that is active when the electrical plug located at the first end of the electrical power cord is connected to a live AC electrical outlet and the emergency stop button is manually pressed.

9. The autonomous unmanned ground vehicle (A-UGV) of claim 5, further comprising an emergency stop button configured to sever an AC electrical connection that is active when the electrical plug located at the first end of the electrical power cord is connected to a live AC electrical outlet, and to sever a DC electrical connection that powers the motor-driven cable reel, when the emergency stop button is manually pressed.

10. The autonomous unmanned ground vehicle (A-UGV) of claim 5, further comprising a circuit breaker configured to sever an AC electrical connection that is active when the electrical plug located at the first end of the electrical power cord is connected to a live AC electrical outlet and the current flowing though the AC electrical connection exceeds a defined limit.

11. The autonomous unmanned ground vehicle (A-UGV) of claim 5, further comprising a shell and at least one vibration dampening mount disposed adjacent to the shell.

12. The autonomous unmanned ground vehicle (A-UGV) of claim 5, further comprising at least one tool configured to receive AC electrical power from the electrical power cord and to operate in response to the AC electrical power.

13. The autonomous unmanned ground vehicle (A-UGV) of claim 5, further comprising:
at least one AC/DC converter configured to receive AC electrical power from the electrical power cord and in response thereto to produce DC electrical power; and
at least one DC motor configured to receive the DC electrical power from the AC/DC converter and to operate in response to the DC electrical power.

14. The autonomous unmanned ground vehicle (A-UGV) of claim 5, wherein the motor-driven cable reel includes at least one hollow shaft, wherein the hollow shaft has a first end and a second end, wherein one or more electrical leads pass through the hollow shaft.

15. The autonomous unmanned ground vehicle (A-UGV) of claim 5, wherein the level wind assembly further comprises a diamond screw having a first end and a second end, wherein at least one end of the diamond screw is partially bored out.
